(19) United States
(12) Patent Application Publication
(10) Pub. No.: US 2017/0352787 A1
(43) Pub. Date: Dec. 7, 2017

(54) STREET LAMP

(71) Applicant: PANASONIC INTELLECTUAL PROPERTY MANAGEMENT CO., LTD., Osaka (JP)

(72) Inventors: Naoko TAKEI, Osaka (JP); Makoto YAMADA, Osaka (JP); Tooru SUZUKI, Osaka (JP)

(73) Assignee: PANASONIC INTELLECTUAL PROPERTY MANAGEMENT CO., LTD., Osaka (JP)

(21) Appl. No.: 15/610,782

(22) Filed: Jun. 1, 2017

(30) Foreign Application Priority Data
Jun. 3, 2016 (JP) 2016-112127

(51) Int. Cl. H01L 33/50; F21S 8/08; H01L 33/62; H01L 33/48; H01L 33/54; F21W 111/023

(52) U.S. Cl. CPC H01L 33/504; H01L 33/62; H01L 33/486; F21S 8/086; F21W 2111/023; H01L 33/54

(57) ABSTRACT

A street lamp includes a light emitter that is disposed at a height of at least 5 m and at most 15 m above a road and emits white light to illuminate the road. The white light has: a correlated color temperature in a range from 5000 K to 6500 K; a chromaticity deviation in a range from −10 to +10; a scotopic/photopic (S/P) ratio of at least 2.0, the S/P ratio being a ratio of a scotopic luminous flux to a photopic luminous flux; and an average horizontal illuminance of at least 5 lx at an illumination area on the road illuminated with the white light.

### CROSS REFERENCE TO RELATED APPLICATION

This application claims the benefit of priority of Japanese Patent Application Number 2016-112127 filed on Jun. 3, 2016, the entire content of which is hereby incorporated by reference.

### BACKGROUND

### 1. Technical Field

The present disclosure relates to a street lamp.

### 2. Description of the Related Art

Illumination devices used to illuminate streets are required to ensure the visibility for pedestrians walking on the streets, drivers of vehicles running on the streets, etc. The human visual sensitivity changes according to the brightness of the surrounding environment, i.e., photopic, scotopic, or mesopic environment. In a photopic environment (in a bright environment), cone cells function to allow human eyes to perceive colors. In a scotopic environment (in a dark environment), cone cells do not function and thus human eyes cannot perceive many colors. Instead, rod cells function to improve the human visual sensitivity.

In a mesopic environment (in a dim environment), which is a combination of a photopic environment and a scotopic environment, both cone and rod cells function. It is said that mesopic vision of human eyes occurs at an illuminance of about 0.01 lx to 10 lx. Thus, photopic vision occurs at an illuminance of at least 10 lx and scotopic vision occurs at an illuminance of at most 0.01 lx.

Here, when the environment changes from a dark environment to a bright environment, the peak of the human visual sensitivity shifts to the shorter wavelength region. Such a phenomenon is well known as the Purkinje phenomenon. Most of cone cells are concentrated in the center of a retina and the number of cone cells decreases rapidly with distance from the center. On the other hand, rod cells are not observed in the center of the retina and the number of rod cells increases rapidly with distance from the center. Therefore, in a mesopic environment, most vehicle drivers use their central vision to visually recognize a roadway and use their peripheral vision to visually recognize a footway.

An example of an illumination device using the Purkinje phenomenon described above is an outdoor illumination device (see, for example, Japanese Unexamined Patent Application Publication No. 2008-091232). The illumination device disclosed in Japanese Unexamined Patent Application Publication No. 2008-091232 includes a roadway side light source portion for illuminating a roadway and a footway side light source portion for illuminating a footway. The roadway side light source portion illuminates the roadway with light having a wavelength corresponding to the wavelength (555 nm) of the peak visual sensitivity of cone cells, which function well in bright environments. On the other hand, the footway side light source portion illuminates the footway with light having a wavelength corresponding to the wavelength (507 nm) of the peak visual sensitivity of rod cells, which function well in dark environments. As described above, most drivers use their peripheral vision to visually recognize the footway. Therefore, when the footway is illuminated with light corresponding to the visual sensitivity of rod cells, the drivers' visibility of the footway side is improved.

### SUMMARY

In the illumination device disclosed in Japanese Unexamined Patent Application Publication No. 2008-091232, however, the color of light emitted from the roadway side light source portion is different from the color of light emitted from the footway side light source portion, and thus pedestrians may perceive color unevenness due to the difference in light color between the roadway side and the footway side.

Therefore, the present disclosure provides a street lamp capable of providing high footway visibility to drivers and providing high visibility to pedestrians with less perception of color unevenness between the roadway side and the footway side in a mesopic environment.

A street lamp according to an aspect of the present disclosure includes a light emitter that is disposed at a height of at least 5 m and at most 15 m above a road and emits white light to illuminate the road. The white light has: a correlated color temperature in a range from 5000 K to 6500 K; a chromaticity deviation in a range from −10 to +10; a scotopic/photopic (S/P) ratio of at least 2.0, the S/P ratio being a ratio of a scotopic luminous flux to a photopic luminous flux; and an average horizontal illuminance of at least 5 lx at an illumination area on the road illuminated with the white light.

According to the street lamp of the present disclosure, it is possible to provide high footway visibility to vehicle drivers and provide high visibility to pedestrians with less perception of color unevenness between the roadway side and the footway side in a mesopic environment.

### BRIEF DESCRIPTION OF DRAWINGS

The figures depict one or more implementation in accordance with the present teaching, by way of examples only, not by way of limitations. In the figures, like reference numerals refer to the same or similar elements.

FIG. 1 is a schematic view illustrating an illumination area illuminated with light by street lamps according to an embodiment;

FIG. 2 is an external perspective view of a street lamp according to the embodiment;

FIG. 3 is a plan view illustrating an internal structure of the street lamp according to the embodiment;

FIG. 4 is an external perspective view illustrating an illumination light source according to the embodiment;

FIG. 5 is a schematic cross-sectional view of the illumination light source, taken along line V-V in FIG. 4;

FIG. 6 is a graph showing a light emission spectrum of a street lamp according to Example 1;

FIG. 7 is a graph showing a light emission spectrum of a street lamp according to Example 2;

FIG. 8 is a graph showing a light emission spectrum of a street lamp according to Example 3;

FIG. 9 is a graph showing a light emission spectrum of an illumination light source according to Comparative Example 1;

FIG. 10 is a graph showing a light emission spectrum of an illumination light source according to Comparative Example 2;

FIG. 11 is a graph showing a light emission spectrum of an illumination light source according to Comparative Example 3;

FIG. 12 is an external perspective view illustrating an illumination light source according to another embodiment; and

FIG. 13 is a schematic cross-sectional view of the illumination light source, taken along line XIII-XIII in FIG. 12.

### DETAILED DESCRIPTION OF THE EMBODIMENTS

Hereinafter, a street lamp according to embodiments will be described with reference to the Drawings. Note that each of the embodiments described below shows a general or specific example. The numerical values, shapes, materials, structural elements, the arrangement and connection of the structural elements, etc. shown in the following embodiments are mere examples, and are not intended to limit the scope of the present disclosure. As such, among the structural elements in the following embodiments, those not recited in any one of the independent claims which indicate the broadest inventive concepts are described as arbitrary structural elements.

Note that the respective figures are schematic illustrations and are not necessarily precise illustrations. Additionally, substantially identical elements are assigned the same reference signs, and there are cases where overlapping descriptions are omitted or simplified.

### Embodiment

(Configuration of Street Lamp)

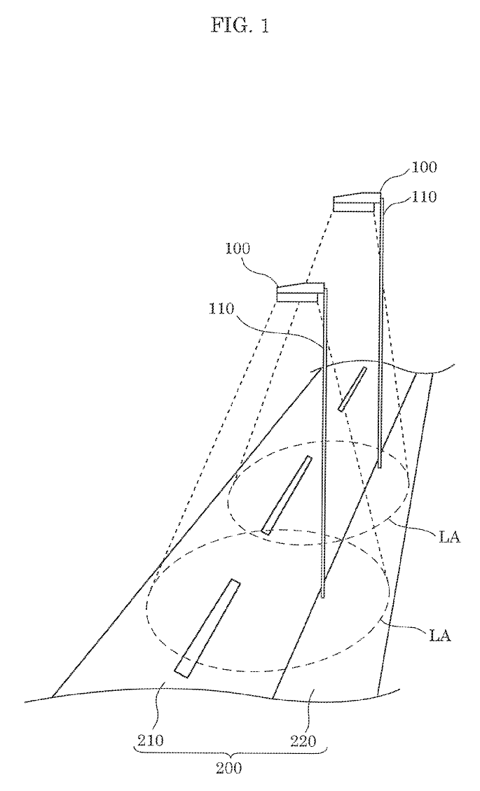

First, a street lamp according to an embodiment will be described. FIG. 1 is a schematic view illustrating an illumination area illuminated with light by the street lamps according to the embodiment. As shown in FIG. 1, street lamps 100 are disposed to illuminate road 200 including roadway 210 and footway 220. Street lamps 100 are each supported above road 200 by pole member 110. Street lamps 100 are used, for example, on a public road or in a factory, a parking lot, or the like. As shown in FIG. 1, a plurality of street lamps 100 are disposed along road 200 at predetermined intervals.

Street lamps 100 illuminate the surface of roadway 210 and the surface of footway 210. Street lamps 100 each illuminate illumination area LA on these surfaces.

Street lamp 100 includes illumination light source 310 described later and thus emits light with improved visibility in a mesopic environment. Street lamp 100 emits light of the same color toward both roadway 210 and footway 220. Street lamp 100 (specifically, light emitter 300 in street lamp 100 shown in FIG. 3) is disposed at a height of at least 5 m and at most 15 m above the surface of road 200. Street lamp 100 is configured to emit light with an illuminance high enough to illuminate illumination area LA with an average horizontal illuminance of at least 5 lx. Here, the term “average horizontal illuminance” refers to the illuminance on a horizontal surface per unit area when illuminated with light. In this specification, the average horizontal illuminance is the average illuminance on illumination area LA on road 200 when street lamp 100 illuminates the surface of road 200.

Thus, when the illumination range of light from street lamp 100 is in a mesopic environment or in a photopic environment, the illuminated space is filled with light with high visibility for pedestrians and drivers. In addition, compared with the case where roadway 210 and footway 220 are illuminated with different color lights, street lamp 100 can contribute to a reduction in color unevenness between roadway 210 and footway 220. Therefore, pedestrians and drivers feel comfortable as if they are in a space filled with uniform light emitted from street lamp 100. Note that the divergence angle of the light emitted from street lamp 100 is not particularly limited as long as road 200 is illuminated with an average horizontal illuminance of at least 5 lx. It is only necessary that street lamp 100 be designed to illuminate roadway 210 and footway 220 efficiently.

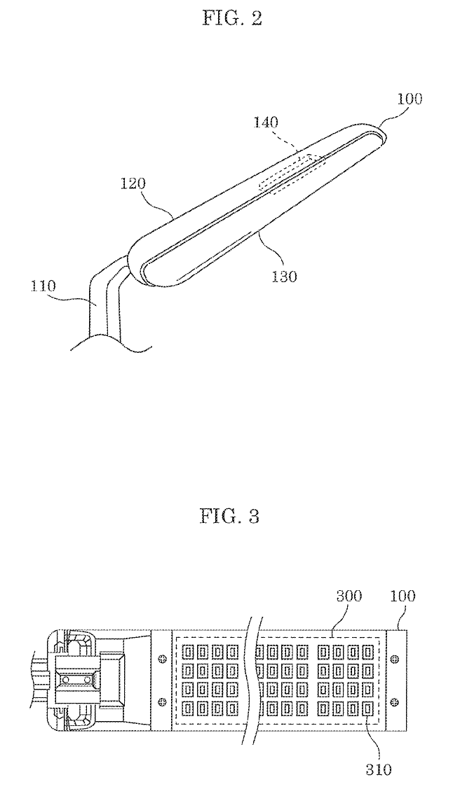

Hereinafter, a detailed configuration of street lamp 100 will be described. FIG. 2 is an external perspective view of street lamp 100 according to the embodiment. Note that FIG. 2 is an external perspective view of street lamp 100, as seen from below, when street lamp 100 is disposed above road 200. FIG. 3 is a plan view illustrating the internal structure of street lamp 100 according to the embodiment, as seen when light-transmissive cover 130 is removed from street lamp 100. As shown in FIG. 2 and FIG. 3, street lamp 100 includes housing 120, light-transmissive cover 130, and light emitter 300.

Housing 120 houses light emitter 300 and holds light-transmissive cover 130 that covers light emitter 300 thus housed. Housing 120 is formed of a metallic material, for example, but may be formed of another material such as a resin material. The inner surface of housing 120 may be formed of a light reflective material to increase the light use efficiency.

Light-transmissive cover 130 is a cover member that transmits light from light emitter 300 and is attached to housing 120. Light-transmissive cover 130 is formed of, for example, a glass material or a transparent resin material such as an acrylic or polycarbonate resin. Note that light-transmissive cover 130 may have light diffusing properties. Alternatively, street lamp 100 does not have to include light-transmissive cover 130.

Light emitter 300 emits white light toward road 200. Specifically, light emitter 300 includes a plurality of illumination light sources 310 arranged in a matrix. As described later, illumination light sources 310 each include, for example, a light-emitting element and a phosphor that converts a portion of light emitted from the light-emitting element into light with a different wavelength. Note that light emitter 300 may include at least one illumination light source 310.

Street lamp 100 may include power source unit 140 that supplies illumination light sources 310 with electric power for lighting illumination light sources 310. For example, power source unit 140 converts AC power supplied from a commercial power supply to DC power so as to output the DC power to illumination light sources 310. Note that power source unit 140 may be included in street lamp 100 or may be placed separately from street lamp 100.

(Configuration of Illumination Light Source)

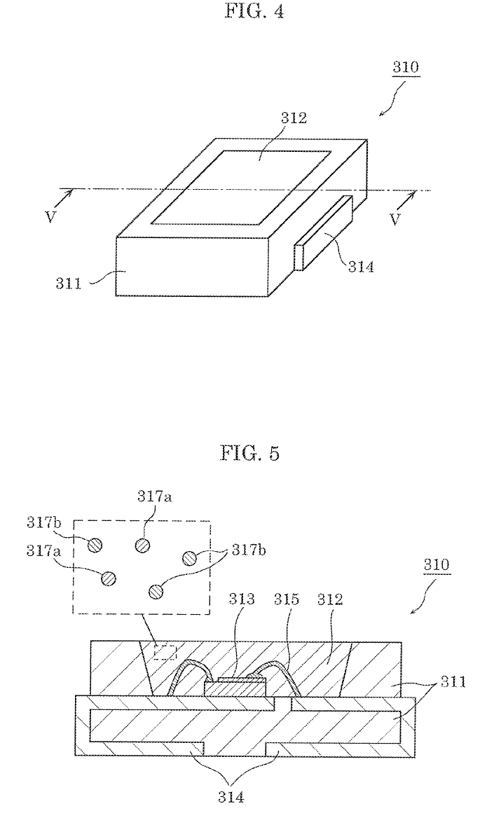

Next, the configuration of illumination light source 310 according to the embodiment will be described with reference to the Drawings. FIG. 4 is an external perspective view of illumination light source 310 according to the embodiment. FIG. 5 is a schematic cross-sectional view of illumination light source 310, taken along line V-V in FIG. 4.

As shown in FIG. 4 and FIG. 5, illumination light source 310 according to the embodiment is implemented as a surface mount device (SMD) light-emitting device. As described later, illumination light source 310 is capable of emitting white light that can be perceived as bright with central vision and peripheral vision in a mesopic environment. Therefore, illumination light source 310 is suitable for use in a street lamp in a dark surrounding environment such as nighttime.

Illumination light source 310 includes container 311 having a cavity, sealing member 312 filling the cavity, and light-emitting diode (LED) chip (light-emitting element) 313 mounted in the cavity.

Container 311 is a container housing LED chip 313 and sealing member 312. Container 311 also includes electrode 314, which is metal wiring for supplying electric power to LED chip 313. LED chip 313 and electrode 314 are electrically connected to each other by bonding wire 315. The material of container 311 is, for example, a metal, a ceramic, or a resin.

As the ceramic, aluminum oxide (alumina), aluminum nitride, or the like is used. As the metal, for example, an aluminum alloy, an iron alloy, a copper alloy, or the like having a surface coated with an insulating film, is used. As the resin, for example, glass epoxy composed of glass fiber and epoxy resin, or the like is used. Note that the above-mentioned materials may be used in combination as the material of container 311.

As the material of container 311, for example, a highly light-reflective material (with an optical reflectivity of at least 90%, for example) may be used. With the use of such a highly light-reflective material for container 311, light emitted by LED chip 313 can be reflected off the surface of container 311. As a result, the light extraction rate of illumination light source 310 is increased. Alternatively, the inner surface of container 311 in which LED chip 313 is mounted may be treated or machined to increase the optical reflectivity.

LED chip 313 is one example of the light-emitting element and is a blue LED chip that emits blue light. For example, LED chip 313 is a gallium nitride-based LED chip made of an indium gallium nitride (InGaN)-based material and having a center wavelength (a peak wavelength of the light emission spectrum) in a range from 430 nm to 460 nm.

Sealing member 312 is a scaling member that seals LED chip 313, bonding wire 315, and at least part of electrode 314. Sealing member 312 contains a wavelength conversion material that converts the wavelength of a portion of light emitted from LED chip 313. Specifically, sealing member 312 is made of a light-transmissive resin material containing a plurality of green phosphors 317a and a plurality of red phosphors 317b, as wavelength conversion materials. The light-transmissive resin material is not particularly limited, but may be a methyl-based silicone resin, an epoxy resin, or a urea resin, for example.

Green phosphor 317a is one example of a phosphor (phosphor particles), which, when excited by blue light emitted from LED chip 313, emits green light having a wavelength different from the wavelength of the blue light emitted from LED chip 313. Specifically, a Lu₃Al₅O₁₂:Ce³⁺ phosphor having a center wavelength of fluorescence in the range from 540 nm to 550 nm is used as green phosphor 317a.

As described later, illumination light source 310 is characterized by an increased S/P ratio of white light which illumination light source 310 emits. Note that the S/P ratio is an index for evaluating the visibility in a mesopic environment. Light having a higher S/P ratio means light having higher visibility in a mesopic environment. In order to increase the S/P ratio, it is effective to increase blue green light in a wavelength range from 480 nm to 520 nm. Furthermore, in order to increase the optical components in such a range of blue green light, it is effective to use a Lu₃Al₅O₁₂:Ce³⁺ phosphor from the perspective of high wavelength conversion efficiency.

When a Lu₃Al₅O₁₂:Ce³⁺ phosphor is used, a center wavelength of fluorescence of less than 540 nm leads to a decrease in the wavelength conversion efficiency. On the other hand, a center wavelength of fluorescence of more than 550 nm leads to a decrease in the effect of increasing the components in the above range of blue green light, that is, the effect of increasing the S/P ratio. Therefore, in this embodiment, the Lu₃Al₅O₁₂:Ce³⁺ phosphor having a center wavelength of fluorescence in the range from 540 nm to 550 nm is used.

Note that if a decrease in the light conversion efficiency can be permitted, any phosphor in the range in which the later-described light emission spectrum can be obtained may be used as green phosphor 317a. For example, an yttrium aluminum garnet (YAG)-based phosphor may be used as green phosphor 317a. Alternatively, for example, a halosilicate-based phosphor may be used as green phosphor 317a. Alternatively, for example, an oxynitride-based phosphor may be used as green phosphor 317a.

Red phosphor 317b is one example of the phosphor, which, when excited by light emitted from LED chip 313, emits red light having a wavelength different from the wavelength of the blue light emitted from LED chip 313. Specifically, a (Sr,Ca)AlSiN₃:Eu²⁺ phosphor having a center wavelength of fluorescence in the range from 610 nm to 620 nm is used as red phosphor 317b. Note that any phosphor may be used as red phosphor 317b as long as the later-described light emission spectrum can be obtained.

With the configuration described above, a portion of the blue light emitted from LED chips 313 is converted by green phosphor 317a contained in sealing member 312, so that the portion is transformed into green light. Likewise, another portion of the blue light emitted from LED chips 313 is converted by red phosphor 317b contained in sealing member 312, so that the portion is transformed into red light. Then, the blue light not absorbed by green phosphor 317a and red phosphor 317b, the green light resulting from the wavelength conversion by green phosphor 317a, and the red light resulting from the wavelength conversion by red phosphor 317b are diffused and mixed within scaling member 312. Consequently, white light is emitted from sealing member 312. This means that illumination light source 310 emits white light resulting from mixing of the light emitted from LED chip 313, the light emitted from green phosphor 317a, and the light emitted from red phosphor 317b.

The following describes Examples 1 to 3 and Comparative Examples 1 to 3 of the light emission spectra of the white light which illumination light source 310 emits.

### Example 1

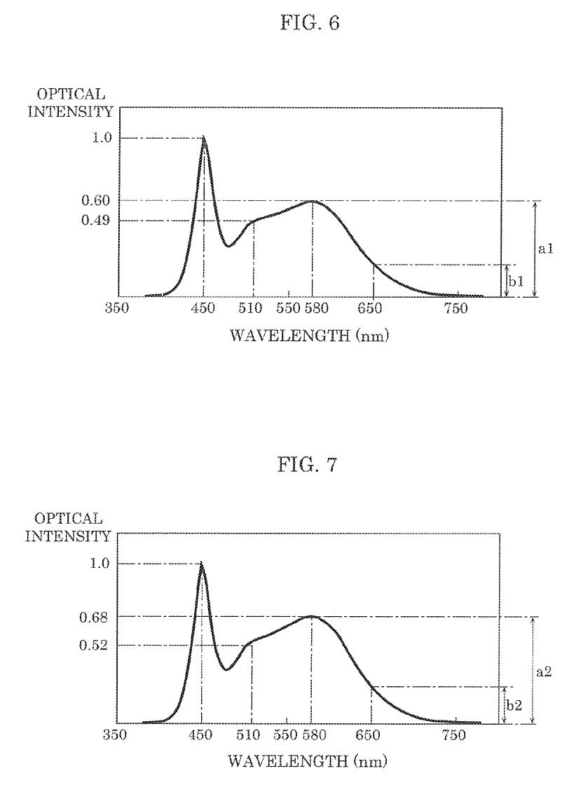

FIG. 6 is a graph showing a light emission spectrum of illumination light source 310 according to Example 1. Note that the vertical axis in FIG. 6 represents normalized optical intensity where light having a wavelength of 450 nm has an optical intensity of 1.0 in the light emission spectrum.

Illumination light source 310 according to Examples 1 includes LED chip 313 having a light emission peak at a wavelength of 450 nm, green phosphor 317a (Lu₃Al₅O₁₂:Ce³⁺ phosphor) having a light emission peak at a wavelength of 545 nm, and red phosphor ((Sr,Ca)AlSiN₃:Eu²⁺ phosphor) having a light emission peak at a wavelength of 615 nm. In illumination light source 310 according to Example 1, an amount of mixture of green phosphor 317a and red phosphor 317b is adjusted so that the white light emitted from illumination light source 310 has a correlated color temperature of 6000 K. Thus, the correlated color temperature of the white light which illumination light source 310 according to Example 1 emits is 6000 K.

As shown in FIG. 6, the proportion of the optical intensity at a wavelength of 510 nm relative to the optical intensity at a first peak (at a wavelength of 450 nm) of the light emission spectrum is 0.49. The proportion of the optical intensity at a wavelength of 580 nm (a1 in FIG. 6) relative to the optical intensity at the first peak of the light emission spectrum is 0.60. The proportion of the optical intensity at a wavelength of 650 nm (b1 in FIG. 6) relative to the optical intensity at the wavelength of 580 nm (b1/a1 in FIG. 6) is 0.34. The light emission spectrum of illumination light source 310 according to Example 1 has a second peak at the wavelength of 580 nm. Note that the second peak means the next highest optical intensity after the light emission peak (i.e., the first peak) at the wavelength of 450 nm.

The white light which illumination light source 310 according to Example 1 emits has a chromaticity deviation (Duv) of 0. The chromaticity deviation as used herein refers to a deviation of color temperature from the blackbody locus. The white light which illumination light source 310 according to Example 1 emits has an average color rendering index (Ra) of 80. The white light which illumination light source 310 according to Example 1 emits has an S/P ratio, which is a ratio of a scotopic luminous flux to a photopic luminous flux, of 2.2.

Note that the S/P ratio is an index for evaluating the visibility in a mesopic environment. Light having a higher S/P ratio means light having higher visibility in a mesopic environment. The S/P ratio (R_{SP}) can be calculated from Expression (1) below, where V(λ) is the spectral luminous efficiency of illumination light source 310 for photopic vision and V′(λ) is the spectral luminous efficiency of illumination light source 310 for scotopic vision, for example.

$$\begin{matrix}[ Math . 1 ] & \\ {R}_{SP} = \frac{{K}^{′} \int {V}^{′} ( λ ) {Φ}_{e} ( λ ) d λ}{K \int V ( λ ) {Φ}_{e} ( λ ) d λ} & Expression ( 1 )\end{matrix}$$

In Expression (1), K is a maximum photopic luminosity factor (=683 lm/W), K′ is a maximum scotopic luminosity factor (=1699 lm/W), and Φₑ(λ) is a total spectral radiant flux of illumination light source 310.

### Example 2

FIG. 7 is a graph showing a light emission spectrum of illumination light source 310 according to Example 2. Note that the vertical axis in FIG. 7 represents normalized optical intensity where light having a wavelength of 450 nm has an optical intensity of 1.0 in the light emission spectrum.

Illumination light source 310 according to Example 2 is the same as illumination light source 310 according to Example 1 except that an amount of mixture of green phosphor 317a and red phosphor 317b is adjusted so that the white light emitted from illumination light source 310 according to Example 2 has a correlated color temperature of 5500 K. Thus, the correlated color temperature of the white light which illumination light source 310 according to Example 2 emits is 5500 K.

As shown in FIG. 7, the proportion of the optical intensity at a wavelength of 510 nm relative to the optical intensity at a first peak (at a wavelength of 450 nm) of the light emission spectrum is 0.52. The proportion of the optical intensity at a wavelength of 580 nm (a2 in FIG. 7) relative to the optical intensity at the first peak of the light emission spectrum is 0.68. The proportion of the optical intensity at a wavelength of 650 nm (b2 in FIG. 7) relative to the optical intensity at the wavelength of 580 nm (b2/a2 in FIG. 7) is 0.35. The light emission spectrum of illumination light source 310 according to Example 2 has a second peak at the wavelength of 580 nm. The white light which illumination light source 310 according to Example 2 emits has a chromaticity deviation of 0. The white light which illumination light source 310 according to Example 2 emits has an average color rendering index of 80. The white light which illumination light source 310 according to Example 2 emits has an S/P ratio of 2.1.

### Example 3

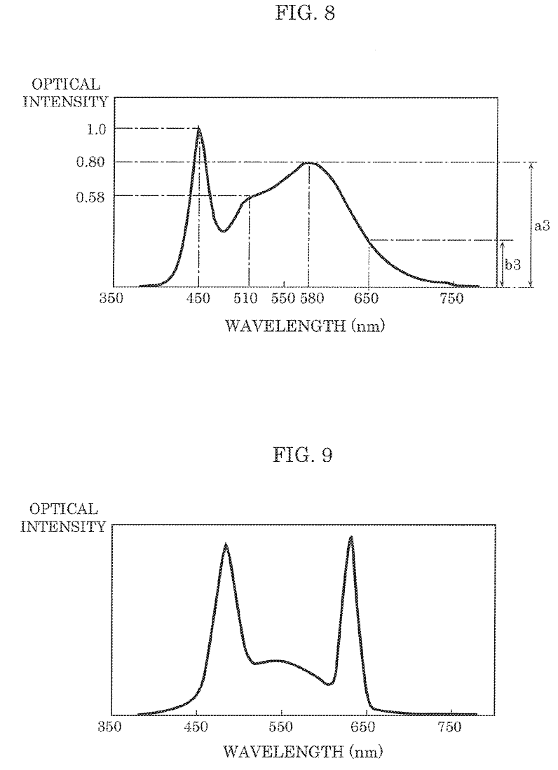

FIG. 8 is a graph showing a light emission spectrum of illumination light source 310 according to Example 3. Note that the vertical axis in FIG. 8 represents normalized optical intensity where light having a wavelength of 450 nm has an optical intensity of 1.0 in the light emission spectrum.

Illumination light source 310 according to Example 3 is the same as illumination light source 310 according to Example 1 except that an amount of mixture of green phosphor 317a and red phosphor 317b is adjusted so that the white light emitted from illumination light source 310 according to Example 3 has a correlated color temperature of 5000 K. Thus, the correlated color temperature of the white light which illumination light source 310 according to Example 3 emits is 5000 K.

As shown in FIG. 8, the proportion of the optical intensity at a wavelength of 510 nm relative to the optical intensity at a first peak (at a wavelength of 450 nm) of the light emission spectrum is 0.58. The proportion of the optical intensity at a wavelength of 580 nm (a3 in FIG. 8) relative to the optical intensity at the first peak of the light emission spectrum is 0.80. The proportion of the optical intensity at a wavelength of 650 nm (b3 in FIG. 8) relative to the optical intensity at the wavelength of 580 nm (b3/a3 in FIG. 8) is 0.37. The light emission spectrum of illumination light source 310 according to Example 3 has a second peak at the wavelength of 580 nm. The white light which illumination light source 310 according to Example 3 emits has a chromaticity deviation of 0. The white light which illumination light source 310 according to Example 3 emits has an average color rendering index of 80. The white light which illumination light source 310 according to Example 3 emits has an S/P ratio of 2.0.

### Comparative Example 1

FIG. 9 is a graph showing a light emission spectrum of an illumination light source according to Comparative Example 1. The illumination light source according to Comparative Example 1 includes a blue green LED chip having a light emission peak at a wavelength of 480 nm, a red LED chip having a light emission peak at a wavelength of 630 nm, and a green phosphor (Y₃Al₅O₁₂:Ce³⁺ phosphor) having a light emission peak at a wavelength of 555 nm. In the illumination light source according to Comparative Example 1, the number of the blue green LED chips, the number of the red LED chips, and an amount of the green phosphor are adjusted so that the white light emitted from the illumination light source has a correlated color temperature of 5500 K. Thus, the correlated color temperature of the white light which the illumination light source according to Comparative Example 1 emits is 5500 K.

The light emission spectrum of the white light which the illumination light source according to Comparative Example 1 emits has the characteristics as shown in FIG. 9. The white light which the illumination light source according to Comparative Example 1 emits has an average color rendering index of 58. The white light which the illumination light source according to Comparative Example 1 emits has an S/P ratio of 2.9.

### Comparative Example 2

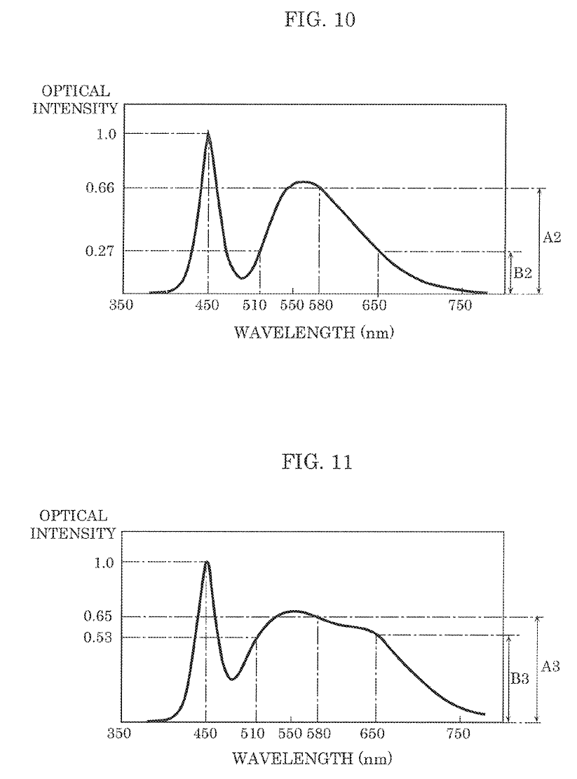

FIG. 10 is a graph showing a light emission spectrum of an illumination light source according to Comparative Example 2. Note that the vertical axis in FIG. 10 represents normalized optical intensity where light having a wavelength of 450 nm has an intensity of 1.0 in the light emission spectrum.

The illumination light source according to Comparative Example 2 has the same overall configuration as that of illumination light source 310, but is different in the phosphor contained in the sealing member. Specifically, the illumination light source according to Comparative Example 2 includes an LED chip having a light emission peak at a wavelength of 450 nm and a green phosphor (Y₃Al₅O₁₂:Ce³⁺ phosphor) having a light emission peak at a wavelength of 555 nm. The illumination light source according to Comparative Example 2 does not include a red phosphor. In the illumination light source according to Comparative Example 2, an amount of mixture of the green phosphor is adjusted so that the white light emitted from the illumination light source has a correlated color temperature of 5000 K. Thus, the correlated color temperature of the white light which the illumination light source according to Comparative Example 2 emits is 5000 K.

As shown in FIG. 10, the proportion of the optical intensity at a wavelength of 510 nm relative to the optical intensity at the peak (at a wavelength of 450 nm) of the light emission spectrum is 0.27. The proportion of the optical intensity at a wavelength of 580 nm (A2 in FIG. 10) relative to the optical intensity at the peak of the light emission spectrum is 0.66. The proportion of the optical intensity at a wavelength of 650 nm (B2 in FIG. 10) relative to the optical intensity at the wavelength of 580 nm (B2/A2 in FIG. 10) is 0.40.

The white light which the illumination light source according to Comparative Example 2 emits has an average color rendering index of 70. The white light which the illumination light source according to Comparative Example 2 emits has an S/P ratio of 1.7.

### Comparative Example 3

FIG. 11 is a graph showing a light emission spectrum of an illumination light source according to Comparative Example 3. Note that the vertical axis in FIG. 11 represents normalized optical intensity where light having a wavelength of 450 nm has an optical intensity of 1.0 in the light emission spectrum.

In the illumination light source according to Comparative Example 3, the sealing member contains a red phosphor ((Sr,Ca)AlSiN₃:Eu²⁺ phosphor) having a light emission peak at a wavelength of 615 nm, in addition to the components of the sealing member of the illumination light source according to Comparative Example 2. In the illumination light source according to Comparative Example 3, an amount of mixture of the green phosphor and the red phosphor is adjusted so that the white light emitted from the illumination light source has a correlated color temperature of 5000 K. Thus, the correlated color temperature of the white light which the illumination light source according to Comparative Example 3 emits is 5000 K.

As shown in FIG. 11, the proportion of the optical intensity at a wavelength of 510 nm relative to the optical intensity at the peak (at a wavelength of 450 nm) of the light emission spectrum is 0.53. The proportion of the optical intensity at a wavelength of 580 nm (A3 in FIG. 11) relative to the optical intensity at the peak of the light emission spectrum is 0.65. The proportion of the optical intensity at a wavelength of 650 nm (B3 in FIG. 11) relative to the optical intensity at the wavelength of 580 nm (B3/A3 in FIG. 11) is 0.83.

The white light which the illumination light source according to Comparative Example 3 emits has an average color rendering index of 90. The white light which the illumination light source according to Comparative Example 3 emits has an S/P ratio of 2.0.

### Advantageous Effects, Etc.

Advantageous effects obtained by illumination light sources 310 according to Examples 1 to 3 described above will be described by comparing Examples 1 to 3 with Comparative Examples 1 to 3 described above.

Each of the light emission spectra of the white light which illumination light sources 310 according to Examples 1 to 3 emit has a light emission peak in the wavelength range from 430 nm to 460 nm. Furthermore, in the light emission spectra of the white light which illumination light sources 310 according to Examples 1 to 3 emit, the proportion of the optical intensity at a wavelength of 510 nm relative to the optical intensity at the peak is at least 0.45, and the proportion of the optical intensity at a wavelength of 580 nm relative to the optical intensity at the peak is at least 0.60. In the light emission spectra of the white light which illumination light sources 310 according to Examples 1 to 3 emit, the proportion of the optical intensity at a wavelength of 650 nm relative to the optical intensity at the wavelength of 580 nm is at most 0.4.

In illumination light source 310 having a light emission spectrum that satisfies these conditions, the optical components of the blue green light in the wavelength range from 480 nm to 520 nm are increased so that the S/P ratio of the white light which illumination light source 310 emits can be increased. Specifically, the S/P ratio of the white light which illumination light source 310 emits can be increased to at least 2.0. Note that the S/P ratio is increased when the peak wavelength of LED chip 313 is shifted to the longer wavelength region. However, the luminous efficiency of LED chip 313 is reduced when the peak wavelength of LED chip 313 is shifted to the longer wavelength region. Therefore, the peak wavelength of LED chip 313 is preferably in a range from 430 nm to 460 nm. Furthermore, the peak wavelength of LED chip 313 is more preferably in a range from 450 nm to 460 nm.

Here, in a photopic environment, cone cells, as one type of photoreceptor cells, having a peak of spectral luminous efficiency at a wavelength of 555 nm are stimulated. In a mesopic environment such as a nighttime street space, not only cone cells but also rod cells having a peak of spectral luminous efficiency at a wavelength of 507 nm are stimulated. In consideration that both cone cells and rod cells are simulated in the mesopic environment, the S/P ratio of the white light which illumination light source 310 emits can be increased by increasing the optical components of the blue green light in the wavelength range from 480 nm to 520 nm in the light emission spectrum.

Note that the S/P ratio is preferably at least 2.0. Light having the S/P ratio of at least 2.0 is perceived as bright particularly with peripheral vision. Note that the peripheral vision refers to the ability to see the peripheral part of a field of view with a visual angle of 10 degrees or more, for example, and is active mainly in a mesopic environment or a scotopic environment. Therefore, illumination light source 310 is capable of emitting white light that can be perceived as bright with peripheral vision in the mesopic environment.

In contrast, for example, the light emission spectrum of the illumination light source according to Comparative Example 2 does not satisfy the condition of an S/P ratio of at least 2.0 mentioned above. In a mesopic environment, the illumination light source according to Comparative Example 2 has lower visibility.

Illumination light source 310 having a light emission spectrum that satisfies the conditions as described above is capable of emitting white light that can be perceived as bright also with central vision in the mesopic environment, due to the shape of the light emission spectrum. Note that the central vision refers to the ability to see the central part of a field of view with a visual angle in a range from about 2 degrees to less than 10 degrees, for example, and is active mainly in a photopic environment.

In contrast, for example, the light emission spectrum of the illumination light source according to Comparative Example 3 does not satisfy the above-mentioned condition that the proportion of the optical intensity at a wavelength of 650 nm relative to the optical intensity at the wavelength of 580 nm is at most 0.4. The illumination light source according to Comparative Example 3 is not capable of providing sufficient brightness with both central vision and peripheral vision at the same time.

Likewise, the light emission spectrum of the illumination light source according to Comparative Example 1 does not satisfy the above-mentioned condition, either. Thus, the white light which the illumination light source according to Comparative Example 1 emits is insufficient in brightness with central vision in a mesopic environment.

The average color rendering index of the white light which illumination light sources 310 according to Examples 1 to 3 emit is at least 80, which indicates high color reproducibility. Therefore, with the use of illumination light sources 310 according to Examples 1 to 3, it is possible to accurately reproduce color information of a sign or the like mounted on or near road 200. Thus, it is possible to reduce errors in color recognition by drivers and pedestrians.

In contrast, for example, the average color rendering index of the white light which the illumination light source according to Comparative Example 1 emits is 58, which indicates low color reproducibility. Therefore, there is a risk of color recognition error for drivers and pedestrians.

Furthermore, the white light which illumination light sources 310 according to Examples 1 to 3 emit has a correlated color temperature in the range from 5000 K to 6500 K. With this, illumination light sources 310 according to Examples 1 to 3 are capable of emitting light of less bluish, natural daylight white (cool daylight color), which allows clear recognition of white lines or the like on road 200. Note that the correlated color temperature of the white light is more preferably in a range from 5200 K to 6000 K. With this, the optical components in the blue region (for example, a wavelength range from 400 nm to 500 nm) of the white light are further reduced, and thus scattering of the illumination light in a fog or the like can be reduced. As a result, driving safety is improved.

The white light which illumination light sources 310 according to Examples 1 to 3 emit has a chromaticity deviation in the range from −10.0 to +10.0. Thus, illumination light sources 310 according to Examples 1 to 3 are capable of emitting neither too greenish nor too reddish and more natural white light. Note that the chromaticity deviation is more preferably in a range from −5.0 to +5.0. Light with this chromaticity deviation is more natural white light, which allows clearer recognition of white lines on road 200, for example.

The lumen equivalents (LE) of the light emission spectrum of light emitted from illumination light sources 310 according to Examples 1 to 3 are all at least 300 lm/W. The lumen equivalent as used herein is an index for evaluating the visibility per equal light energy in a photopic environment. In other words, light with a high lumen equivalent is understood as light with high visibility per equal light energy in a photopic environment, that is, light that can be easily detected by cone cells. Furthermore, illumination with a high lumen equivalent is understood as illumination that can be easily detected by cone cells even in a mesopic environment. The lumen equivalent can be calculated from Expression (2) below, where K is a maximum photopic luminosity factor (=683 lm/W), V(λ) is spectral luminous efficiency with photopic vision, and Φₑ(λ) is a total spectral radiant flux of illumination light source 310.

$$\begin{matrix}[ Math . 2 ] & \\ LE = \frac{K {\int }_{380}^{780} V ( λ ) {Φ}_{e} ( λ ) d λ}{{\int }_{380}^{780} {Φ}_{e} ( λ ) d λ} & Expression ( 2 )\end{matrix}$$

Thus, the light emitted from illumination light source 310 is light with a high proportion of optical components that can be easily detected by cone cells even in a mesopic environment. Therefore, the light emitted from illumination light source 310 is perceived as bright both with peripheral vision and central vision in a mesopic environment and thus has improved light energy use efficiency.

The characteristics of the light emitted from illumination light sources 310 according to Examples 1 to 3 and the effects obtained from this light have been described above. However, it is not always necessary that the light emitted from each of illumination light sources 310 placed in street lamp 100 have the above-described characteristics and effects as long as the light emitted from street lamp 100 have these characteristics and effects. For example, the street lamp may include a light emitter including blue LED chips that emit blue light and a light-transmissive cover containing a green phosphor and a red phosphor. For example, the street lamp thus configured may be adapted such that the light emitted from the street lamp has a light emission spectrum as shown in Examples 1 to 3 described above.

(Variation 1)

Insects attracted to street lamp 100 may cause troubles such as failure of street lamp 100. In order to reduce the attraction of insects to street lamp 100, the correlated color temperature of a portion of the white light emitted in a horizontal direction from street lamp 100 may be lower than the correlated color temperature of a portion of the white light emitted in a vertical direction from street lamp 100. In other words, the correlated color temperature of a portion of the light emitted downwardly and outwardly from street lamp 100 may be lower than the correlated color temperature of a portion of the light emitted downwardly and inwardly from street lamp 100. In the white light which illumination light source 310 emits, the optical energy emitted from a phosphor in the horizontal direction may be higher than the optical energy emitted from the phosphor in the vertical direction. In other words, in the white light which illumination light source 310 emits, the optical intensity of light having a light emission peak in a wavelength range from 430 nm to 460 nm and emitted in the horizontal direction may be lower than the optical intensity of light having a light emission peak in that wavelength range and emitted in the vertical direction.

It is generally understood that insects are attracted to light in the blue region (for example, light in a wavelength range from 400 nm to 500 nm). Light emitted from street lamp 100 is directed toward illumination area LA, but a portion of the emitted light reaches a region outside illumination area LA due to reflection from the road surface, etc. Therefore, a portion of the light emitted from street lamp 100 in a more horizontal direction toward illumination area LA is more likely to reach further than a portion of the light emitted in the vertical direction from street lamp 100. This means that insects located far away from street lamp 100 are more likely to perceive the portion of the light emitted from street lamp 100 in a more horizontal direction.

Therefore, the attraction of insects is reduced by lowering the correlated color temperature of the portion of the light emitted in the horizontal direction, that is, by emitting less insect-attractive white light having fewer blue light components. Thus, street lamp 100 is capable of providing high footway visibility to drivers of vehicles, providing less perception of color unevenness to pedestrians, and reducing attraction of insects.

Note that the configuration to reduce attraction of insects is not particularly limited to a specific one. For example, it may be possible to configure street lamp 100 including a plurality of illumination light sources 310 such that the emission color of some of illumination light sources 310 disposed in the peripheral region is different from the emission color of the other illumination light sources 310 disposed in the central region. For example, when light emitter 300 includes a plurality of illumination light sources 310 disposed therein, it is possible to configure light emitter 300 such that the peak optical intensity in a wavelength range from 430 nm to 460 nm of white light emitted from illumination light sources 310 disposed in the peripheral region is lower than the peak optical intensity of white light emitted from illumination light sources 310 disposed in the central region.

As a specific configuration for reducing attraction of insects, it is also possible to coat the peripheral portion of light-transmissive cover 130 with a phosphor so as to convert a portion of the blue light components included in the white light emitted from illumination light source 310 in a more horizontal direction into green light or red light. As another configuration for reducing attraction of insects, for example, it is possible to intentionally change the content of a phosphor in sealing member 312 so that the content of the phosphor in the peripheral region of sealing member 312, as viewed from the front of the light-emitting surface of illumination light source 310, is higher than the content in other regions.

(Variation 2)

In some cases, a camera for imaging road 200 is set up to detect abnormalities on or around road 200. In such a case, light emitted from street lamp 100 may cause noise in the image taken by the camera.

On road 200, optical components in the red region (for example, in a wavelength range from 600 nm to 700 nm) are used for a red traffic light, a brake light, or the like to provide alerts in emergency situations. Here, if the white light which street lamp 100 emits contains a high proportion of optical components in the red region, the proportion of the components in the red region in the white light which street lamp 100 emits at nighttime may be higher than the proportion in daytime (i.e., a time of day during which the surrounding area is illuminated not by street lamp 100 but by sunlight). In such a case, a camera sensor is saturated with red light, which may cause noise in the resulting image.

In view of this, in the light emission spectrum of the white light emitted from light emitter 300, the proportion of the optical energy of a portion of the white light having a wavelength of at least 620 nm relative to the total optical energy of the white light may be lower than 0.2.

It is possible to reduce noise in the image taken by the camera by reducing the proportion of the optical energy of light having a wavelength of at least 620 nm, which corresponds to optical components in the red region, in the white light of street lamp 100. Note that in the white light which each of illumination light sources 310 according to Examples 1 to 3 emits, the proportion of the optical energy of a portion of the white light having a wavelength of at least 620 nm relative to the total energy of the white light is lower than 0.2.

(Conclusion)

Street lamp 100 according to the embodiment includes light emitter 300 that is disposed at a height of at least 5 m and at most 15 m above road 200 and emits white light to illuminate road 200. This white light has: a correlated color temperature in a range from 5000 K to 6500 K; a chromaticity deviation in a range from −10 to +10; and an S/P ratio, which is a ratio of a scotopic luminous flux to a photopic luminous flux, of at least 2.0. The white light has an average horizontal illuminance of at least 5 lx at illumination area LA on road 200 illuminated with the white light. This white light emitted from street lamp 100 eliminates the need to illuminate roadway 210 and footway 220 separately, and thus reduces color unevenness between different spaces. In addition, this white light emitted from street lamp 100 eliminates the need to illuminate roadway 210 and footway 220 separately and thus can be perceived as bright with both central vision and peripheral vision. Therefore, pedestrians and drivers feel comfortable as if they are in a well-lit space. This results in improved visibility of the condition of roadway 210, condition at the side of road 200, pedestrians on footway 220, etc. for drivers of moving vehicles. In addition, the visibility of signs such as white lines on road 200 is improved for the drivers. On the other hand, for the pedestrians on footway 220, the visibility of their footsteps perceived with central vision is improved because the spaces around their feet are illuminated with white light that can be perceived as bright with central vision. As a result, the safety of walking pedestrians is improved. Furthermore, since spatially uniform white light is emitted toward both roadway 210 and footway 220, pedestrians are less likely to perceive color unevenness.

The white light emitted from street lamp 100 may have an average color rendering index of at least 80. With this white light, drivers and pedestrians can perceive colors more accurately, and thus can recognize the color information of a sign or the like mounted on or near road 200 more accurately. It is also possible to reduce errors in recognition such as color recognition of pedestrians' clothes and vehicles.

The white light emitted from street lamp 100 may have a light emission spectrum having a lumen equivalent of at least 300 lm/W and a peak in a wavelength range from 430 nm to 460 nm. In the light emission spectrum, the proportion of the optical intensity at a wavelength of 510 nm relative to the optical intensity at the peak may be at least 0.45, and the proportion of the optical intensity at a wavelength of 580 nm relative to the optical intensity at the peak may be at least 0.60. Furthermore, in the light emission spectrum, the proportion of the optical intensity at a wavelength of 650 nm relative to the optical intensity at the wavelength of 580 nm may be at most 0.4. Thus, the white light emitted from street lamp 100 is white light that makes drivers and pedestrians feel bright with less energy loss.

The correlated color temperature of a portion of the white light emitted in a horizontal direction from street lamp 100 may be lower than a correlated color temperature of a portion of the white light emitted in a vertical direction from street lamp 100. Thus, insects located far away from street lamp 100 are less likely to perceive the white light emitted from street lamp 100. As a result, attraction of insects is reduced.

The proportion of the optical energy of a portion of the white light having a wavelength of at least 620 nm relative to the total optical energy of the white light may be lower than 0.2. Thereby, the proportion of the optical components in the red region contained in the white light emitted from street lamp 100 is reduced, and thus saturation of a camera sensor with red light can be reduced. As a result, noise caused by saturation with red light is reduced in an image taken by a camera.

Furthermore, light emitter 300 of street lamp 100 may include illumination light source 310. Illumination light source 310 may include light-emitting element 313 and a plurality of phosphors each of which is excited by light emitted from light-emitting element 313 and emits light having a wavelength different from a wavelength of the light emitted from light-emitting element 313. Furthermore, light-emitting element 313 may have a light emission peak in a wavelength range from 430 nm to 460 nm. This means that LED chip 313 having a light emission peak in a wavelength range from 430 nm to 460 nm, for example, is used as light-emitting element 313. Thus, illumination light source 310 is capable of emitting light that can be perceived as bright with both peripheral and central visions and having improved color reproducibility.

Furthermore, the plurality of phosphors may include a Lu₃Al₅O₁₂:Ce³⁺ phosphor having a light emission peak in a wavelength range from 540 nm to 550 nm. This means that a Lu₃Al₅O₁₂:Ce³⁺ phosphor having high light conversion efficiency in the blue green region, for example, is used as the phosphor. Thus, illumination light source 310 is capable of efficiently emitting light that can be perceived as bright with both peripheral and central visions and having improved color reproducibility.

Furthermore, the plurality of phosphors may include a (Sr,Ca)AlSiN₃:Eu²⁺ phosphor having a light emission peak in a wavelength range from 610 nm to 620 nm. This means that a (Sr,Ca)AlSiN₃:Eu²⁺ phosphor having high light conversion efficiency in the red region, for example, is used as the phosphor. Thus, illumination light source 310 is capable of emitting light that can be perceived as bright with both peripheral and central visions and having improved color reproducibility.

### Other Embodiments

Although the street lamp according to the embodiment has been described above, the present disclosure is not limited to the above-described embodiment.

Although illumination light source 310 including container 311 and light-emitting element 313 mounted in container 311 has been described in the above embodiment, the present disclosure is not limited to this embodiment. Illumination light sources according to the other embodiments are described below.

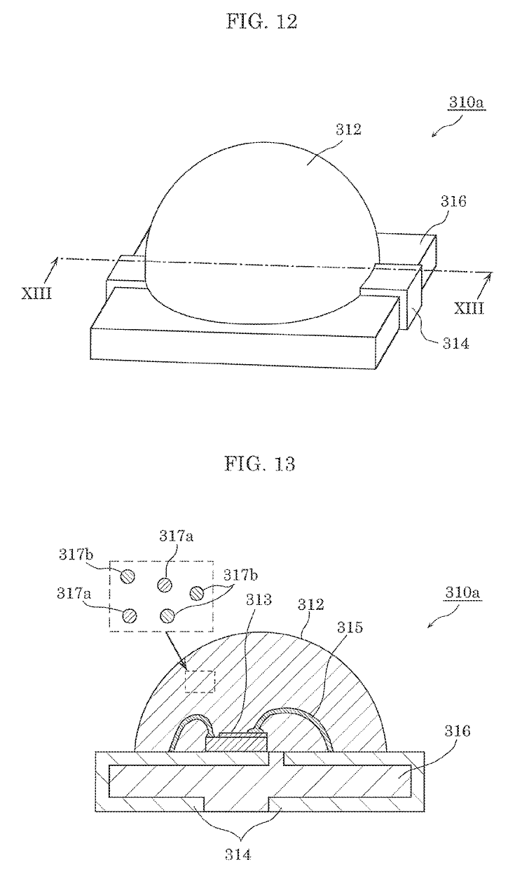

FIG. 12 is an external perspective view illustrating an illumination light source according to another embodiment. FIG. 13 is a schematic cross-sectional view of the illumination light source, taken along line XIII-XIII in FIG. 12. As shown in FIG. 12 and FIG. 13, illumination light source 310a includes substrate 316 and LED chip (light-emitting element) 313 mounted on substrate 316.

Substrate 316 is a substrate having a wiring region on which electrode 314 is provided. Note that electrode 314 is metal wiring for supplying electric power to LED chip 313. Substrate 316 is, for example, a metal-based substrate or a ceramic substrate. Furthermore, substrate 316 may be a resin substrate made of a resin as a base material.

A highly light-reflective substrate (with an optical reflectivity of at least 90%, for example) may be used as substrate 316. The use of a highly light-reflective substrate as substrate 316 allows light emitted from LED chip 313 to be reflected off the surface of substrate 316. As a result, the light extraction efficiency of illumination light source 310a is increased. Examples of such a substrate include a white ceramic substrate made of alumina as a base material.

Note that substrate 316 has a rectangular shape in the other embodiment, but may have any other shape such as a circular shape.

Sealing member 312 is a sealing member that seals LED chip 313, bonding wire 315, and at least a part of electrode 314. Sealing member 312 contains a wavelength conversion material that converts the wavelength of a portion of light emitted from LED chip 313. Specifically, sealing member 312 is made of a light-transmissive resin material containing a plurality of green phosphors 317a and a plurality of red phosphors 317b, as wavelength conversion materials.

Sealing member 312 of illumination light source 310a is formed in a dome shape having a radius of curvature on substrate 316. Specifically, as shown in FIG. 13, sealing member 312 formed on substrate 316 has an approximately semicircular cross section. Sealing member 312 thus formed is capable of collecting light emitted from LED chip 313 and light emitted from the wavelength conversion members sealed in sealing member 312. In other words, sealing member 312 formed with a radius of curvature has a function as a lens for collecting the above lights.

Note that the cross-sectional shape of sealing member 312 formed on substrate 316 is not limited. The emission angles of light from illumination light source 310a and light from the street lamp including illumination light source 310a can be changed to desired angles by changing the radius of curvature of sealing member 312 to be formed. Illumination light source 310a and the street lamp including illumination light source 310a thus configured are capable of illuminating a predetermined range of road 200 without an additional member such as a lens.

In the above embodiment, the light emission spectrum as described above is obtained using two different types of phosphors and one LED chip (light-emitting element). However, this embodiment is merely an example, and any type of phosphor and any type of light-emitting element may be used as long as they satisfy the above-mentioned conditions.

For example, an LED chip is used as a specific example of a light-emitting element in Examples 1 to 3. However, a semiconductor light-emitting element, such as a semiconductor laser, or a solid-state light-emitting element, such as an electroluminescence (EL) element including an organic or inorganic EL material, may be used as the light-emitting element. Furthermore, for example, the illumination light source may include at least three types of phosphors having different center wavelengths of fluorescence. In both cases, when the above-described conditions of the light emission spectrum are satisfied, the street lamp is capable of emitting light that can be perceived as bright both with peripheral vision and central vision.

Furthermore, for example, although the above embodiment has described an illumination light source implemented as a SMD light-emitting module, the illumination light source of the present disclosure may be implemented as a so-called chip-on-board (COB) LED module in which an LED chip is directly mounted on a substrate.

Furthermore, the illumination light source of the present disclosure may be implemented as a remote phosphor light-emitting module in which a resin member containing a phosphor is provided away from the LED chip.

Furthermore, the street lamp of the present disclosure may be implemented as a remote phosphor illumination device in which a resin member containing a phosphor is provided away from the LED chip.

Furthermore, the shape, structure, and size of the street lamp of the present disclosure are not particularly limited; the street lamp of the present disclosure only needs to satisfy the conditions of the light emission spectrum described in the above embodiment.

While the foregoing has described one or more embodiments and/or other examples, it is understood that various modifications may be made therein and that the subject matter disclosed herein may be implemented in various forms and examples, and that they may be applied in numerous applications, only some of which have been described herein. It is intended by the following claims to claim any and all modifications and variations that fall within the true scope of the present teachings.

What is claimed is:

1. A street lamp comprising
a light emitter that is disposed at a height of at least 5 m and at most 15 m above a road and emits white light to illuminate the road,
wherein the white light has:
a correlated color temperature in a range from 5000 K to 6500 K;
a chromaticity deviation in a range from −10 to +10;
a scotopic/photopic (S/P) ratio of at least 2.0, the S/P ratio being a ratio of a scotopic luminous flux to a photopic luminous flux; and
an average horizontal illuminance of at least 5 lx at an illumination area on the road illuminated with the white light.

2. The street lamp according to claim 1,
wherein the white light has an average color rendering index of at least 80.

3. The street lamp according to claim 1,
wherein the white light has a light emission spectrum having:
a lumen equivalent of at least 300 lm/W; and
a peak in a wavelength range from 430 nm to 460 nm, and in the light emission spectrum,
a proportion of optical intensity at a wavelength of 510 nm relative to optical intensity at the peak is at least 0.45,
a proportion of optical intensity at a wavelength of 580 nm relative to the optical intensity at the peak is at least 0.60, and
a proportion of optical intensity at a wavelength of 650 nm relative to the optical intensity at the wavelength of 580 nm is at most 0.4.

4. The street lamp according to claim 1,
wherein a correlated color temperature of a portion of the white light emitted in a horizontal direction is lower than a correlated color temperature of a portion of the white light emitted in a vertical direction.

5. The street lamp according to claim 1,
wherein a proportion of optical energy of a portion of the white light having a wavelength of at least 620 nm relative to total optical energy of the white light is lower than 0.2.

6. The street lamp according to claim 1,
wherein the light emitter includes an illumination light source,
the illumination light source includes:
a light-emitting element; and
a plurality of phosphors each of which is excited by light emitted from the light-emitting element and emits light having a wavelength different from a wavelength of the light emitted from the light-emitting element, and
the light-emitting element has a light emission peak in a wavelength range from 430 nm to 460 nm.

7. The street lamp according to claim 6,
wherein the plurality of phosphors include a Lu₃Al₅O₁₂:Ce³⁺ phosphor having a light emission peak in a wavelength range from 540 nm to 550 nm.

8. The street lamp according to claim 6,
wherein the plurality of phosphors include a (Sr,Ca)AlSiN₃:Eu²⁺ phosphor having a light emission peak in a wavelength range from 610 nm to 620 nm.
